(19) United States
(12) Patent Application Publication
(10) Pub. No.: US 2005/0145889 A1
(43) Pub. Date: Jul. 7, 2005

(54) Solid state image pickup device and its manufacture method

(75) Inventor: Eiichi Okamoto, Kurokawa-gun (JP)

Correspondence Address: ARENT FOX PLLC, 1050 CONNECTICUT AVENUE, N.W., SUITE 400, WASHINGTON, DC, 20036, US

(73) Assignee: FUJI PHOTO FILM CO., LTD.

(21) Appl. No.: 11/002,891

(22) Filed: Dec. 3, 2004

(30) Foreign Application Priority Data
Dec. 26, 2003 (JP) 2003-433075

(51) Int. Cl. H01L 31/0203

(52) U.S. Cl. 257/215

(57) ABSTRACT

A solid state image pickup device includes: a semiconductor substrate photoelectric conversion elements disposed in rows and columns; vertical charge transfer channels disposed in a vertical direction between adjacent columns of the photoelectric conversion elements; a read gate region formed for reading signal charges accumulated in a corresponding photoelectric conversion element to an adjacent one of the vertical charge transfer channels; a channel stop region formed adjacent to the vertical transfer channel; and a multi-layer transfer electrode formed extending in a horizontal direction above each of the vertical transfer channels, the multi-layer transfer electrode transferring signal charges read by a corresponding one of the vertical transfer channels and including an upper electrode and a lower electrode, wherein at least one of the upper and lower electrodes has a layout area broader than the other in an overlap portion between the upper and lower electrodes.

### CROSS REFERENCE TO RELATED APPLICATION

This application is based on and claims priority of Japanese Patent Application No. 2003-433075 filed on Dec. 26, 2003, the entire contents of which are incorporated herein by reference.

### BACKGROUND OF THE INVENTION

A) Field of the Invention

The present invention relates to a solid state image pickup device, and more particularly to the layout of transfer electrodes of a solid state image pickup device.

B) Description of the Related Art

Many CCD type solid state image pickup devices use multi-layer polysilicon electrodes as the transfer electrodes of a vertical transfer circuit. For example, refer to Japanese Patent Laid-open Publication No. HEI-06-005596, which is incorporated herein by reference.

FIG. 5 is an enlarged plan view showing an example of the layout of transfer electrodes of a conventional solid state image pickup device.

In a light reception area of a solid state image pickup device 50, a number of photoelectric conversion elements 52 are disposed along a plurality of rows and columns. A vertical transfer channel 54 is formed along each column of the photoelectric conversion elements 52. The vertical transfer channel 54 transfers signal charges in a vertical direction, the signal charges being read via a read gate channel region 51c formed adjacent to each photoelectric conversion element 52. A channel stop region 53 is formed adjacent to the vertical transfer channel 54 on the side opposite to the read gate channel region 51c. A multi-layer polysilicon electrode 56 is formed above the vertical transfer channel 54, with an unrepresented insulating film being interposed therebetween.

If a mask pattern for an overlap portion 56ov of the transfer electrode 56 (a first layer polysilicon electrode 56a and a second layer polysilicon electrode 56b) has a straight line layout as indicated by a dotted line, the corner of each transfer electrode is rounded by photolithography processes, and the transfer channel 54 just under the overlap portion 56ov of the transfer electrodes 56 is exposed in some cases.

Since the electrodes of the two layer are overlapped in the overlap portion 56ov, the upper second polysilicon electrode may have an undercut during the etching process, and the transfer channel 54 under the undercut is exposed.

As the transfer channel 56 is exposed, the vertical transfer channel 54 has locally an area not covered with the transfer electrode 56, resulting in a defective transfer of signal charges in some cases and in a degraded transfer efficiency.

### SUMMARY OF THE INVENTION

An object of this invention is to provide a solid state image pickup device capable of mitigating a defective transfer of signal charges in a transfer path.

Another object of this invention is to provide a method of manufacturing a solid state image pickup device capable of mitigating a defective transfer of signal charges in a transfer path.

According to one aspect of the present invention, there is provided a solid state image pickup device comprising: a semiconductor substrate defining a two-dimensional surface; a number of photoelectric conversion elements disposed in a light reception area of the semiconductor substrate in a plurality of rows and columns; a plurality of vertical charge transfer channels disposed in a vertical direction between adjacent columns of the photoelectric conversion elements; a read gate region formed for each of the photoelectric conversion elements for reading signal charges accumulated in a corresponding photoelectric conversion element to an adjacent one of the vertical charge transfer channels along a row direction; a channel stop region formed adjacent to the vertical transfer channel on a side opposite to the read gate region of a corresponding one of the photoelectric conversion elements, the channel stop region electrically separating the vertical transfer channel of a corresponding photoelectric conversion element column from the vertical transfer channels of other photoelectric conversion element columns; and a multi-layer transfer electrode formed extending in a horizontal direction above each of the vertical transfer channels, the multi-layer transfer electrode transferring signal charges read by a corresponding one of the vertical transfer channels and including an upper electrode and a lower electrode, wherein at least one of the upper and lower electrodes has a layout area broader than the other in an overlap portion between the upper and lower electrodes.

According to another aspect of the present invention, there is provided a method of manufacturing a solid state image pickup device, comprising steps of: preparing a semiconductor substrate defining a two-dimensional surface; forming a number of photoelectric conversion elements disposed in a light reception area of the semiconductor substrate in a plurality of rows and columns; forming a plurality of vertical charge transfer channels disposed in a vertical direction between adjacent columns of the photoelectric conversion elements; forming a read gate region for each of the photoelectric conversion elements for reading signal charges accumulated in a corresponding photoelectric conversion element to an adjacent one of the vertical charge transfer channels along a row direction; forming a channel stop region adjacent to the vertical transfer channel on a side opposite to the read gate region of a corresponding one of the photoelectric conversion elements, the channel stop region electrically separating the vertical transfer channels of a corresponding photoelectric conversion element column from the vertical transfer channels of other photoelectric conversion element columns; and forming a multi-layer transfer electrode extending in a horizontal direction above each of the vertical transfer channels, the multi-layer transfer electrode transferring signal charges read by a corresponding one of the vertical transfer channels and including an upper electrode and a lower electrode, wherein at least one of the upper and lower electrodes has a layout area broader than the other in an overlap portion between the upper and lower electrodes.

It is possible to provide a solid state image pickup device capable of mitigating a defective transfer of signal charges in a transfer path.

It is also possible to provide a method of manufacturing a solid state image pickup device capable of mitigating a defective transfer of signal charges in a transfer path.

### BRIEF DESCRIPTION OF THE DRAWINGS

FIG. 1 is a block diagram showing the structure of a CCD type solid state image pickup device 1 according to an embodiment of the invention.

FIG. 2 is an enlarged plan view showing a partial area of a light reception area 2 of the solid state image pickup device 1 of the embodiment.

FIG. 3 is an enlarged cross sectional view of the solid state image pickup device 1 of the embodiment.

FIG. 4 is an enlarged plan view showing a partial area of the light reception area 2 of the solid state image pickup device 1 disposed in a so-called pixel shift layout.

FIG. 5 is an enlarged plan view showing an example of the layout of transfer electrodes of a conventional solid state image pickup device.

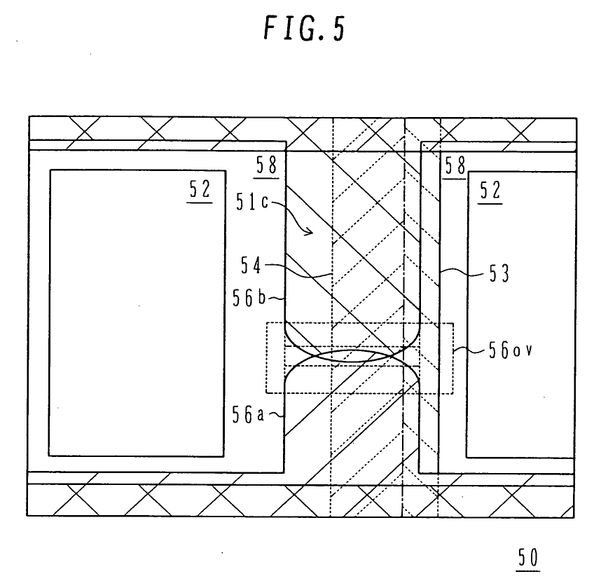

### DESCRIPTION OF THE PREFERRED EMBODIMENTS

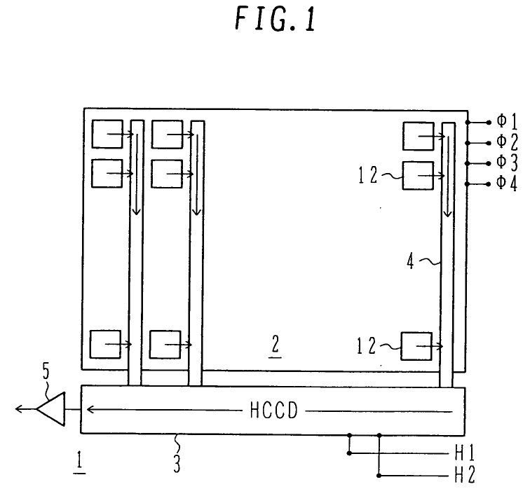

FIG. 1 is a block diagram showing the structure of a CCD type solid state image pickup device 1 according to an embodiment of the invention.

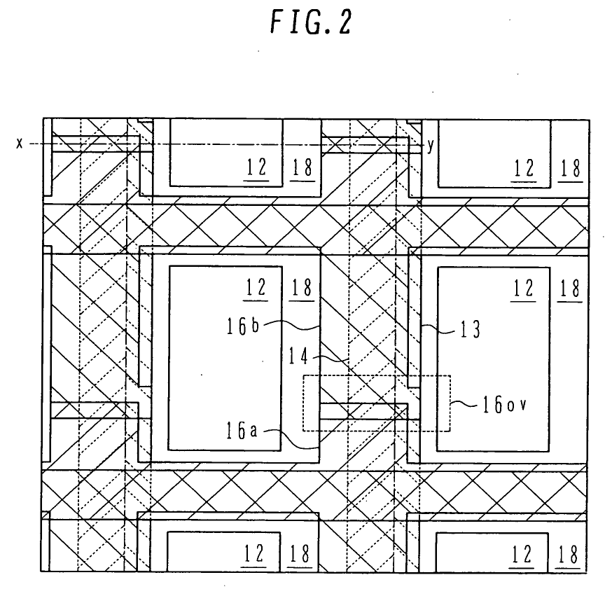

The solid state image pickup device 1 has a light reception area 2 in which a number of photoelectric conversion elements 12 are disposed in a square lattice shape. Between adjacent columns of the photoelectric conversion elements 12, a vertical charge transfer path (VCCD) 4 is disposed to read signal charges generated in each photoelectric conversion element 12 and transfer the charges in a vertical direction. VCCD 4 includes transfer electrodes 16 and a vertical transfer channel 14 shown in FIG. 2. Signal charges generated in the photoelectric conversion elements 12 are transferred vertically by four-phase drive pulses (φ1-φ4).

A horizontal charge transfer path (HCCD) 3 is formed at a position lower than the light reception area 2 as viewed in FIG. 1 to transfer charges of one row transferred by VCCDs to a peripheral circuit 5 formed outside of the light reception area 2.

The peripheral circuit 5 is made of, for example, metal oxide semiconductor (MOS) transistor circuits and includes a floating diffusion amplifier (FDA) and the like.

FIG. 2 is an enlarged plan view showing a partial area of the light reception area 2 of the solid state image pickup device 1 in the state that an insulating film above the semiconductor substrate is removed to expose the photoelectric conversion elements 12 and transfer electrodes 16.

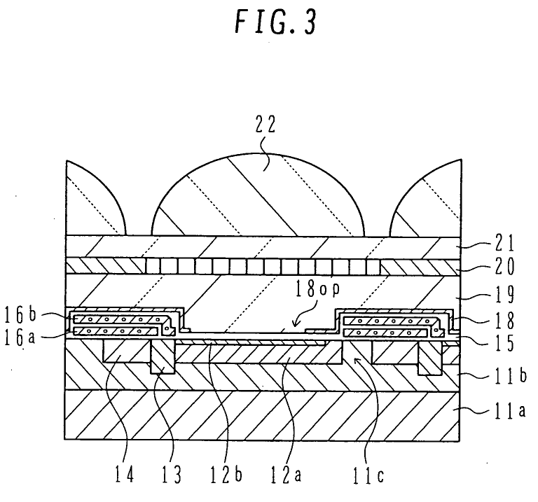

FIG. 3 is an enlarged cross sectional view of the photoelectric conversion element 1 taken along a one-dot chain line x-y shown in FIG. 2.

In the following description, in order to distinguish between impurity concentrations of the same conductivity type, the terms “a p⁻-type impurity doped region”, “a p-type impurity doped region” and a p⁺-type impurity doped region” and the terms “an n⁻-type impurity doped region”, “an n-type impurity doped region” and “an n⁺-type impurity doped region” are used in the order of lower impurity concentration to higher impurity concentration. All impurity doped regions are preferably formed by ion implantation and later heat treatment, except that a p⁻-type impurity doped region 11b may be formed by epitaxial growth.

A semiconductor substrate 11 has, for example, an n⁻-type silicon substrate 11a and the p⁻-type impurity doped region 11b formed on the substrate. The p⁻-type impurity doped region 11b is formed by implanting p-type impurity ions into the n⁻-type silicon substrate 11a and thereafter annealing the implanted ions, or by epitaxially growing p-type impurity containing silicon on the surface of the substrate 11a.

An n-type impurity doped region (vertical transfer channel) 14 having a width of, for example, 0.5 μm is formed in the p⁻-type impurity doped region 11b. The vertical transfer channel 14 extends along a corresponding photoelectric conversion element column to be later formed and has generally a uniform impurity concentration over the whole length of the channel.

A channel stop region 13 is formed adjacent to the vertical transfer channel 14 (on the side opposite to a read gate channel region 11c). For example, the channel stop region 13 is formed by a p⁺-type impurity doped region, trench isolation or local oxidation of silicon (LOCOS).

The p⁻-type impurity doped region 11b is partially used as the p⁻-type impurity doped region 11c along a right edge of each photoelectric conversion element 12 (an n-type impurity doped region 12a) to be later formed. The p⁻-type impurity doped region 11c functions as a read gate channel region 11c.

An oxide film (ONO film) 15 is formed on the surface of the semiconductor substrate 11. For example, the ONO film is made of a lamination film of a silicon oxide film (thermally oxidized film) having a thickness of about 20 to 70 nm, a silicon nitride film having a thickness of about 30 to 80 nm and a silicon oxide film having a thickness of about 10 to 50 nm deposited in this order on the semiconductor substrate 11. In FIG. 3, the oxide film 15 is shown as one layer for the purposes of convenience. Instead of the ONO film, a single oxide film (SiO₂) may be used.

Next, an electrode forming process is executed. In this process, a transfer electrode (multi-layer polysilicon electrode) 16 is formed on the oxide film 15. On the oxide film 15 formed on the surface of the semiconductor substrate 1, a first polysilicon layer 16a is deposited to a thickness of 0.2 μm to 3 μm (e.g., 1 μm). A photoresist film is coated on the first polysilicon layer 16a and patterned by photolithography (exposure, development) to form a photoresist pattern. By using this photoresist pattern as a mask, the exposed first polysilicon layer 1 6a in a mask-less area is etched to form a first layer polysilicon electrode 16a having a straight layout as shown in FIG. 2. This etching is dry etching with high anisotropy (high etching speed along the direction vertical to the mask surface) using chlorine containing gas or the like.

Next, an SiO₂ film (second oxide film) is formed to a thickness of 3,000 nm to 10,000 nm by oxidizing silicon surface, covering the first layer polysilicon electrode 16a. On the second oxide film, a second polysilicon layer 16b is deposited to a thickness of 0.2 μm to 3 μm (e.g., 1 μm) by low pressure CVD or the like. Then, the second polysilicon layer 16b is patterned by photolithography to form a second polysilicon electrode 16b.

As shown in FIG. 3, the first and second polysilicon electrodes 16a and 16b are patterned in the following manner. In an overlap portion 16ov of the polysilicon electrode 16, the portion where the first polysilicon electrode 16a and second polysilicon electrode 16b are overlapped and the portion where the second polysilicon electrode 16b extends outward from the end of the first layer polysilicon electrode 16a, e.g., by about 0.05 μm to 0.1 μm, are extended toward the channel stop region 13 side (opposite to the read gate channel region 11c), e.g., by 0.05 μm or longer.

The layout of the overlap portion 16ov described above is not limitative. For example, the mask pattern for patterning the second polysilicon layer 16b may be formed by extending it toward the channel stop region 13 side, and the extended portion of the overlap portion 16ov may be finally removed by a later etching process or the like. Also in this case, the mask pattern is formed by extending it toward the channel stop region 13 side (opposite to the read gate channel region 11c) in order not to expose the vertical transfer channel 14 just under the overlap portion 16ov.

In this embodiment, the overlap portion 16ov or the portion of the mask pattern corresponding to the overlap portion 16ov for pattering the second layer polysilicon layer 16b is extended toward only the channel stop region 13 side (opposite to the read gate channel region 11c). However, this portion may be formed extending toward both the channel stop region 13 side and the read gate channel region 11c side.

In this specification, the “overlap portion” is intended to mean the region where the first layer polysilicon electrode 16a and second layer polysilicon electrode 16b are overlapped and its peripheral region.

Next, impurity ions are implanted into a predetermined region of the p⁻-type impurity doped region 11b to form an n-type impurity region 12a functioning as a charge accumulation region. Impurity ions are implanted into a surface layer of the n-type impurity doped region 12a to form a p⁺-type impurity doped region 12b so that a photoelectric conversion element 12 can be formed as a buried type photodiode.

Next, an insulating film 15 is formed covering the multi-layer polysilicon electrode 16 and the surface of the silicon substrate 11. A light shielding film 18 is formed on the insulating film 15 by depositing metal such as tungsten, aluminum, chromium, titanium and molybdenum, alloy of two or more these metals, or the like by PVD or CVD. The light shielding film 18 covers each transfer electrode 16 and other areas as viewed in plan to prevent wasteful photoelectric conversion in the area other than the photoelectric conversion elements 12.

The light shielding film 18 has an opening 18op above each photoelectric conversion element 12 to allow light be incident upon the photoelectric conversion element 12. A light incidence plane of the photoelectric conversion element 12 corresponds to the surface of the photoelectric conversion element 12 exposed in the opening 18op as viewed in plan.

Thereafter, a first planarizing layer 19 including a passivation layer and a planarizing insulating layer is formed covering the light shielding film 18. A color filter layer 20 is formed by sequentially forming three or four color resin layers having different colors in predetermined areas by photolithography or the like. For a solid state image pickup device used by a single plate color image pickup device, a primary color or complementary color filter layer 20 is formed. For a black-and-white solid state image pickup device or a solid state image pickup device used by a three-plate image pickup device, the color filter layer 20 can be omitted.

Similar to the first planarizing film 19, a second planarizing film 21 is formed by using organic material such as photoresist. On the upper surface of the second planarizing film 21, a micro lens 22 is formed at a position corresponding to each photoelectric conversion element 12. For example, the micro lens 22 is formed by forming a transparent resin layer on the second planarizing film 21, patterning it to form lens films having a predetermined shape, and reflowing each lens film. The second planarizing film 21 formed on the color filer layer 20 presents a flat surface on which micro lenses 22 are formed.

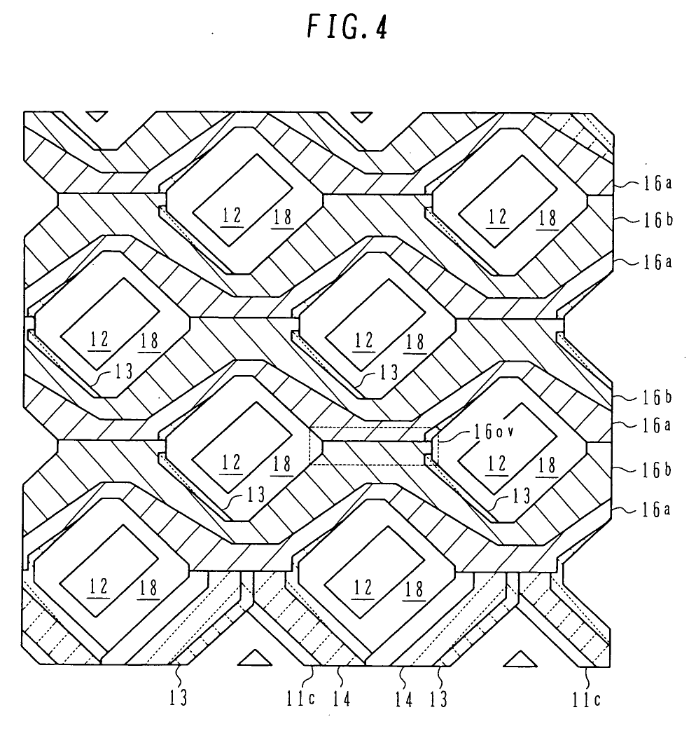

FIG. 4 is an enlarged plan view partially showing the light reception area of the solid state image pickup device 1 of this embodiment structured in a so-called pixel shift layout. In FIG. 4, elements represented by the identical reference numerals to those shown in FIGS. 1 to 3 are elements similar to those shown in FIGS. 1 to 3. FIG. 4 shows the state that the transfer electrodes 16 are removed to expose the underlying transfer channels 14, channel stop regions 13 and read gate channel region 11c.

The light reception area 2 is formed by disposing a number of photoelectric conversion elements 12 (including the n-type impurity doped regions 12a and buried p⁺-type impurity doped regions 12b) in the so-called pixel shift layout. The “pixel shift layout” used in this specification is the layout of a combination of a first lattice of a two-dimensional tetragonal matrix and a second lattice of a two-dimensional tetragonal matrix having lattice points at the positions between the first lattice. For example, each photoelectric conversion element 12 in the odd number photoelectric conversion element column (row) is shifted in the column (row) direction by about a half pitch of photoelectric conversion elements 12 in the column (row) direction from each photoelectric conversion element in the even number photoelectric conversion element, and that each photoelectric conversion element column contains only even or odd photoelectric conversion elements. The “pixel shift layout” is one of the layouts wherein a number of photoelectric conversion elements are disposed in a plurality of rows and columns and in a matrix shape.

The phrase “about a half pitch of photoelectric conversion elements in the column (row) direction” is intended to include also the pitch regarded as substantially equal to the half pitch from the performance and image quality although this pitch is different from the correct half pitch because of manufacture tolerances, rounding errors of pixel positions to be caused by design or mask manufacture, or the like.

An n-type transfer channel region (vertical transfer channel) 14 is disposed along a vertical direction in a zigzag shape between adjacent columns of the photoelectric conversion element 12. The vertical transfer channel 14 reads signal charges generated in the photoelectric conversion elements 12 and transfers them in the vertical direction. The adjacent vertical transfer channels disposed in a zigzag way in a space formed by the pixel shift layout become nearer to each other via the photoelectric conversion elements and become farther from each other via the channel stop regions 13. Almost the whole area of the light reception region of the semiconductor substrate is efficiently used by the photoelectric conversion elements and vertical transfer channels.

Above the vertical transfer channels 14, a transfer electrode 16 (first layer polysilicon electrodes 1 6a and second layer polysilicon electrodes 16b) are formed along the horizontal direction in a zigzag shape in a space between adjacent photoelectric conversion elements 12, with an insulating film (not shown) being interposed therebetween. Four electrodes are disposed for each pixel. Almost the whole area of the transfer electrodes is disposed on the transfer channels.

The transfer electrodes 16 together with the vertical transfer channels 14 constitute vertical charge transfer paths (VCCDs) and transfer signal charges-generated in the photoelectric conversion elements in the vertical direction by using four-phase pulses (φ1-φ4).

Similar to the square lattice layout shown in FIG. 2, even if the solid state image pickup device 1 is structured in the so-called pixel shift layout, in the overlap portion 16ov of the polysilicon electrode 16, the portion where the first polysilicon electrode 16a and second polysilicon electrode 16b are overlapped and the portion where the second polysilicon electrode 16b extends outward from the end of the first layer polysilicon electrode 16a, e.g., by about 0.05 μm to 0.1 μm, are extended toward the channel stop region 13 side (opposite to the read gate channel region 11c), e.g., by 0.05 μm or longer.

The layout of the overlap portion 16ov described above is not limitative. For example, the mask pattern for patterning the second polysilicon layer 16b may be formed by extending it toward the channel stop region 13 side, and the extended portion of the overlap portion 16ov may be finally removed by a later etching process or the like. Also in this case, the mask pattern is formed by extending it toward the channel stop region 13 side (opposite to the read gate channel region 11c) in order not to expose the vertical transfer channel 14 just under the overlap portion 16ov.

According to the embodiment of the invention, since the overlap portion of the multi-layer transfer electrode or its mask pattern has a broader layout area, it is possible to prevent the transfer channel from being exposed and not covered with the transfer electrode, so that the defective transfer can be mitigated.

Since the overlap portion of the upper layer electrode (e.g., second layer polysilicon electrode) on the lower layer electrode (e.g., first layer polysilicon electrode) or its mask pattern has a layout area broader than the lower layer electrode, it is possible to prevent the transfer channel from being exposed by an undercut likely to be formed in the upper electrode by etching. Accordingly, it is possible to prevent the transfer channel from being exposed and not covered with the transfer electrode, so that the defective transfer can be mitigated.

In the above-described embodiment, although only the overlap portion of the upper electrode of the multi-layer transfer electrode or its mask pattern has a layout broader than for the other electrode, the overlap portion of the lower electrode (e.g., first layer polysilicon electrode) or its mask pattern may also have a layout area broader than for the other electrode, similar to the upper electrode.

The present invention has been described in connection with the preferred embodiments. The invention is not limited only to the above embodiments. It will be apparent to those skilled in the art that other various modifications, improvements, combinations, and the like can be made.

1. A solid state image pickup device comprising:
a semiconductor substrate defining a two-dimensional surface;
a number of photoelectric conversion elements disposed in a light reception area of said semiconductor substrate in a plurality of rows and columns;
a plurality of vertical charge transfer channels disposed in a vertical direction between adjacent columns of said photoelectric conversion elements;
a read gate region formed for each of said photoelectric conversion elements for reading signal charges accumulated in a corresponding photoelectric conversion element to an adjacent one of said vertical charge transfer channels along a row direction;
a channel stop region formed adjacent to said vertical transfer channel on a side opposite to said read gate region of a corresponding one of said photoelectric conversion elements, said channel stop region electrically separating said vertical transfer channel of a corresponding photoelectric conversion element column from said vertical transfer channels of other photoelectric conversion element columns; and
a multi-layer transfer electrode formed extending in a horizontal direction above each of said vertical transfer channels, said multi-layer transfer electrode transferring signal charges read by a corresponding one of said vertical transfer channels and including an upper electrode and a lower electrode, wherein at least one of said upper and lower electrodes has a layout area than the other in an overlap portion between said upper and lower electrodes.

2. The-solid state image pickup device according to claim 1, wherein said upper electrode of said multi-layer electrode has a layout area broader than said lower electrode in the overlap portion between said upper and lower electrodes.

3. The solid state image pickup device according to claim 1, wherein said multi-layer electrode has a layout area extending toward a channel stopper region side in the overlap portion between said upper and lower electrodes.

4. The solid state image pickup device according to claim 1, wherein each of said photoelectric conversion elements is disposed at each lattice point of a first square lattice of a square matrix and a second square lattice having lattice points at positions between adjacent lattice points of the first square lattice.

5. A method of manufacturing a solid state image pickup device, comprising steps of:
preparing a semiconductor substrate defining a two-dimensional surface;
forming a number of photoelectric conversion elements disposed in a light reception area of said semiconductor substrate in a plurality of rows and columns;
forming a plurality of vertical charge transfer channels disposed in a vertical direction between adjacent columns of said photoelectric conversion elements;
forming a read gate region for each of said photoelectric conversion elements for reading signal charges accumulated in a corresponding photoelectric conversion element to an adjacent one of said vertical charge transfer channels along a row direction;
forming a channel stop region adjacent to said vertical transfer channel on a side opposite to said read gate region of a corresponding one of said photoelectric conversion elements, said channel stop region electrically separating said vertical transfer channels of a corresponding photoelectric conversion element column from said vertical transfer channels of other photoelectric conversion element columns; and
forming a multi-layer transfer electrode extending in a horizontal direction above each of said vertical transfer channels, said multi-layer transfer electrode transferring signal charges read by a corresponding one of said vertical transfer channels and including an upper electrode and a lower electrode, wherein at least one of said upper and lower electrodes has a layout area broader than the other in an overlap portion between said upper and lower electrodes.

6. The method of manufacturing a solid state image pickup device according to claim 5, wherein said multi-layer electrode forming step forms in such a manner that said upper electrode has a layout area broader than for said lower electrode in the overlap portion between said upper and lower electrodes.

7. The method of manufacturing a solid state image pickup device according to claim 5, wherein said multi-layer electrode has a layout area extending toward a channel stopper region side in the overlap portion between said upper and lower electrodes.

8. The method of manufacturing a solid state image pickup device according to claim 5, wherein each of said photoelectric conversion elements is disposed at each lattice point of a first square lattice of a square matrix and a second square lattice having lattice points at positions between adjacent lattice points of the first square lattice.
